(19) United States
(12) Patent Application Publication
(10) Pub. No.: US 2004/0109507 A1
(43) Pub. Date: Jun. 10, 2004

(54) Sequential decoding of parity check codes

(76) Inventors: Ido Kanter, Rehovot (IL); Haggai Kfir, Kfar Sirkin (IL); Ilan Sutskover, Hadera (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/310,985

(22) Filed: Dec. 6, 2002

(51) Int. Cl. H04L 27/00; H03M 13/00; H04L 27/06; H03D 1/00

(52) U.S. Cl. 375/259; 375/340; 714/752

(57) ABSTRACT

A signal encoded with a linear block code is iteratively decoded using a sequential updating method. The sequential updating method calculates check-to-variable messages and variable-to-check messages such that intra-iteration information is exchanged. In some embodiments, a partial horizontal pass of a column of the matrix is followed by a vertical pass of the column using the results of the partial horizontal pass. In other embodiments, a partial vertical pass of a row of the matrix is followed by a horizontal pass of the row using the results of the partial vertical pass.

### BACKGROUND OF TEE INVENTION

Low density parity check (LDPC) codes, are linear block codes with a sparse parity-check matrix. Originally introduced in the 1960's by Gallager, these codes approach the Shannon limit of channel capacity. Message passing algorithms may be used for iteratively decoding LDPC codes. Belief-propagation algorithms are one type of message passing algorithms. Some non-limiting examples of belief-propagation algorithms are “sum-product” and “min-sum” algorithms and approximations thereof.

It is well known that as the noise level in a channel increases, the decoding time (measured in algorithm iterations) increases too. For this reason, it is beneficial to reduce the number of iterations required for converging, since an accelerated decoder will provide smoother information flow when operating near the channel's capacity.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is a simplified block-diagram illustration of an exemplary communication system, in accordance with some embodiments of the present invention;

FIG. 2 is a simplified block-diagram illustration of a decoder, in accordance with some embodiments of the present invention;

FIG. 3 is a simplified illustration of a matrix, helpful in understanding some embodiments of the present invention;

FIG. 4 is a flowchart illustration of a sequential updating method for decoding, according to some embodiments of the present invention;

FIGS. 5A and 5B show the distribution of the convergence times (measured in number of iterations) for a single-processor parallel updating method and the sequential updating method of FIG. 4;

FIGS. 6A and 6B show the ratio between the converging time in sequential/parallel per sample; and

FIG. 7 presents a table of exemplary measurements for other rates and noise levels.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However it will be understood by those of ordinary slkill in the art that the present invention may be practiced without these specific details. In other instances, well-known methods, procedures, components and circuits have not been described in detail so as not to obscure the present invention.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

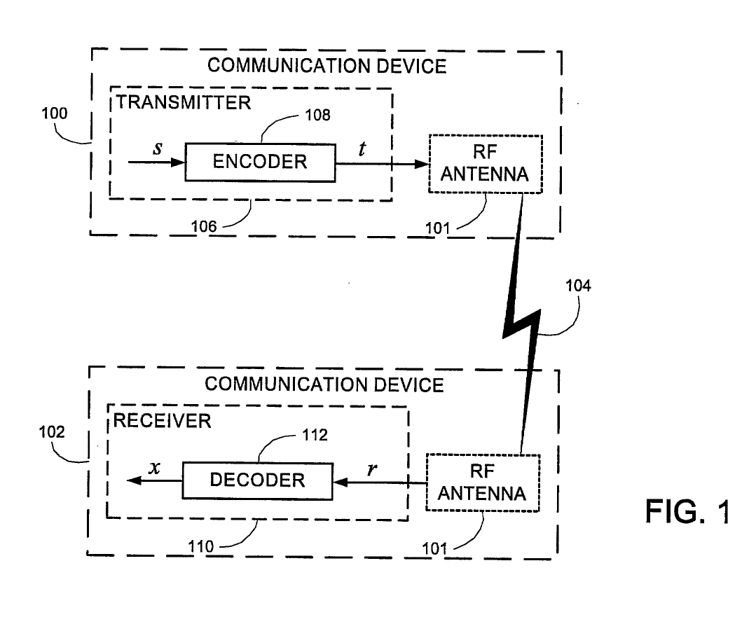

FIG. 1 is a simplified block-diagram illustration of an exemplary communication system, in accordance with some embodiments of the present invention. A communication device 100 is able to communicate with a communication device 102 over a communication channel 104.

Although the present invention is not limited in this respect, communication devices 100, 102 may comprise wire or wireless or cable modems of computers and communication channel 104 may be a wide-area-network (WAN) or local-area-network (LAN). For example, the system may be a wireless LAN system or a digital subscriber line (DSL) system. Alternatively, although the present invention is not limited in this respect, the communication system shown in FIG. 1 may be part of a cellular communication system, with one of communication devices 100, 102 being a base station and the other a mobile station or with both communication devices 100, 102 being mobile stations, a pager communication system, a personal digital assistant and a server, etc. In such cases, communication devices 100 and 102 may each comprise a radio frequency antenna 101. In particular, the communication system shown in FIG. 1 may be a 3^{rd} Generation Partnership Project (3GPP), such as, for example, Frequency Domain Duplexing (FDD) Wideband Code Division Multiple Access (WCDMA) cellular system and the like.

Communication device 100 may comprise a transmitter 106 that may comprise an encoder 108. Communication device 102 may comprise a receiver 110 that may comprise a decoder 112.

Encoder 108 may encode a word s with a linear block code into a codeword t. The linear block code may be represented by a parity-check matrix. Codeword t may be modulated, up-converted and transmitted through communication channel 104, which may be a noisy channel. Receiver 110 may receive a signal from communication channel 104, which after down-conversion and demodulation, may be identified as a received word r. Although the present invention is not limited in this respect, the noise from communication channel 104 may be an additive noise 71, and received word r may be given by r=t+n.

Decoder 112 may use the parity-check matrix in an attempt to determine from received word r the word s that was encoded and transmitted. This is known generally as the ‘decoding problem’.

Many different algorithms may be used for the decoding problem, and an output x from decoder 112 will depend on the algorithm used. Moreover, both the output x and the representation of the decoding problem will depend upon the construction of the linear block code. It is intended that embodiments of the present invention are applicable to all algorithms operating by passing messages between symbols of the code and parity-check constraints used for the decoding of linear block codes.

Although the present invention is not limited in this respect, the following description uses the example of a binary symbol alphabet. Persons of ordinary skill in the art will be able to modify the described embodiments to accommodate a larger symbol alphabet without undue experimentation.

Although the present invention is not limited in this respect, the following description uses the example of low-density parity-check codes, having sparse parity-check matrices.

An exemplary construction, known as Mackay-Neal (MN) codes, will now be described. In this example, MN codes are implemented for binary low-density parity-check (LDPC) codes. Encoder 108 may encode binary word s of size K into binary codeword t of size N, by:

t=B⁻¹·A·s(mod2),

where A is a sparse binary matrix of dimensions (N×K) and B is a sparse, binary and invertible matrix of dimensions (N×N). Receiver 110 may receive a signal from communication channel 104, which after downconversion and demodulation, may be identified as received binary word r, given by r=(t+n)(mod2).

If matrix B is multiplied by the received binary word a, and the product is denoted z, as im z=B r, then the following identity holds:

z=B·r=B·(t+n)=B·(B⁻¹·A·s+n)=A·s+B·n=[A,B]·[s,n]^{T},

where [,] stands for appending matrices and concatenating vectors and the superscript T stands for the transpose operation. The unknowns in this identity are s and n.

Denoting [s,n] as a variable vector x, and [A, B] as a matrix H, which is of dimension (N×(N+K)), the identity above thus becomes H·x=z(mod2). The vector z is a constraints (checks) vector. In this context, the ‘decoding problem’ amounts to finding x.

Different algorithms may lead to different results for x. For example, one algorithm may try to find the most probable variable vector x satisfying H·x=z(mod2). In another example, the “min-sum” algorithm may try to find the most probable partial variable vector x satisfiing H·x=z(mod2), with other criteria for the remaining symbols of x. In yet another example, the “sum-product” algorithm may try to find each symbol of x that is the most probable in view of z. In the “sum-product” algorithm and the like, the resulting vector of most probable symbols may not necessarily satisfy H·x=z(mod2), so error-correcting methods may then be applied to the resulting vector.

In the well-known Gallager scheme, H still has the form [A,B], although different matrices A and B and different vectors are constructed, and the decoding problem takes the form of H·n=r(mod2).

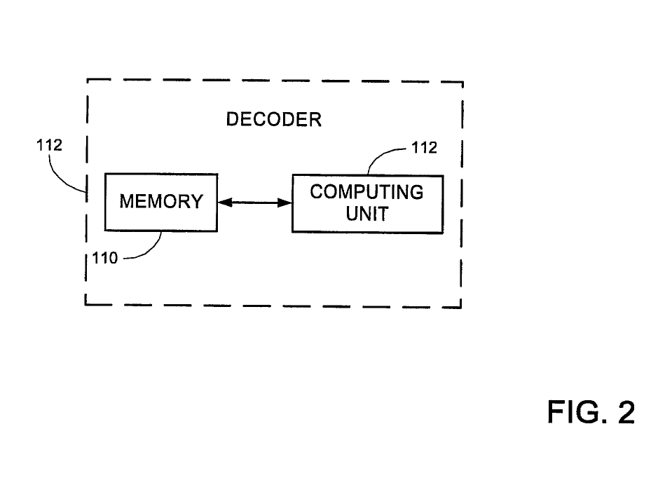

Methods according to some embodiments of the present invention may be implemented in a decoder in software, hardware or any combination thereof. FIG. 2 is a simplified block-diagram illustration of an exemplary decoder, in accordance with some embodiments of the present invention. Decoder 112 comprises a computing unit 200 and a memory 202 coupled to computing unit 200. Although the present invention is not limited in this respect, computing unit 200 may be an application specific integrated circuit (ASIC), a reduced instruction set circuit (RISC), a digital signal processor (DSP) or a central processing unit (CPU). Instructions to enable computing unit to perform methods of embodiments of the present invention may be stored in memory 202.

As is known in the art, the elements of H may be referred to as edges on a bipartite graph representing the connections between elements of x and z. Variable vector x is associated with columns of H and checks vector z is associated with rows of H. It is intended that embodiments of the present invention are applicable to all algorithms used for the decoding of bipartite graphs that pass messages between their edges. Although the present invention is not limited in this respect, the messages may comprise variable-to-check messages and check-to-variable messages.

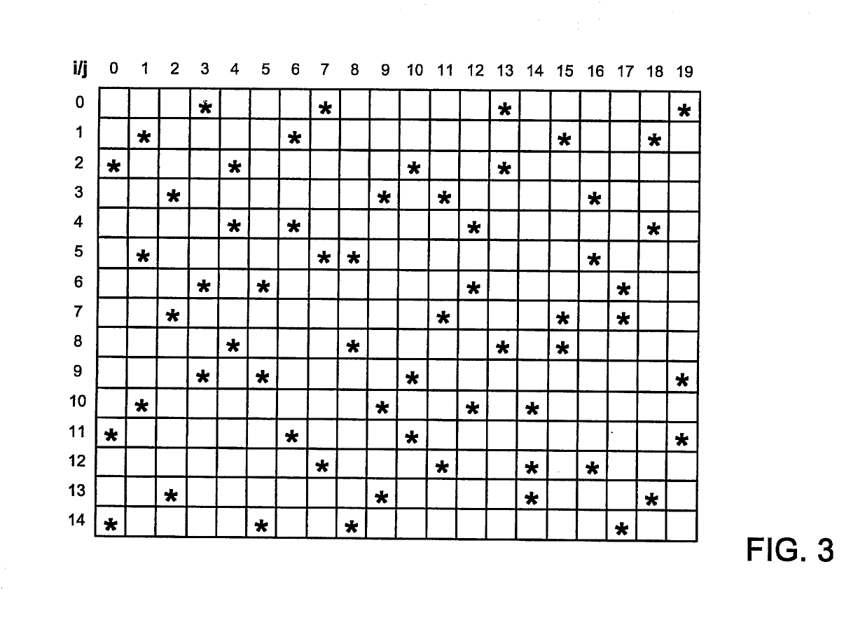

Reference is now made to FIG. 3, which is a simplified illustration of a matrix, where asterisks indicate non-zero elements of the matrix. For simplicity, the matrix illustrated is 15×20 (K 5, N=15, coding rate=1/3), although it will be appreciated by persons of ordinary skill in the art that N and K may be large numbers. For simplicity of explanation, the matrix illustrated has 4 non-zero elements per row and 3 non-zero elements per column, although it will be appreciated by persons of ordinary skill in the art that since H is a sparse matrix for an LDPC code, the matrix illustrated has too many non-zero elements. Although it is not illustrated as such in FIG. 3, in some embodiments of the present invention, matrix B has a cyclic form.

As is known in the art, the non-zero elements in a row i of H represent the symbols of x participating in the corresponding check za. The non-zero elements in a column j represent the checks that xⱼ (the j^{th} symbol of x), participates in. For example, with reference to FIG. 3, symbols 3, 7, 13 and 19 participate in the check z₀, and symbol 10 of x participates in the checks z₂, z₉ and z₁₁.

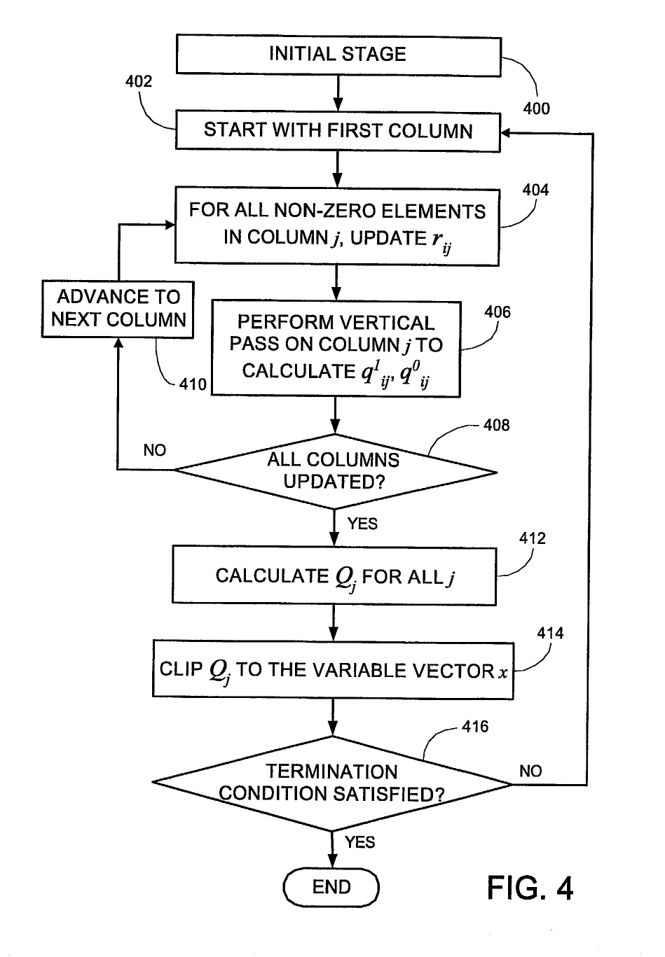

Reference is also made to FIG. 4, which is a flowchart illustration of a sequential updating method for decoding, in accordance with some embodiments of the present invention. The method comprises an initial stage (block 400) and then a number of iterations (blocks 402 through 416) that are repeated until one of the termination conditions is satisfied. The termination conditions may comprise achieving convergence (i.e. the symbols of x for that iteration satisfy the constraint H·x=z(mod2)), reaching a steady state, and exceeding a predetermined number of iterations.

In each iteration, for every non-zero element of matrix H, four quantities are calculated/updated:

qᵢⱼ⁰ (qᵢⱼ¹) represents the probability that the symbol xⱼ (the j^{th} symbol of x), is 0 (1), taking into account the information of all checks it participates in, except the i^{th} check zᵢ; and

rᵢⱼ⁰ (rᵢⱼ¹) represents the probability of the i^{th} check zᵢ being satisfied if symbol xⱼ (the j^{th} symbol of x) is considered fixed at 0 (1) and the other symbols of x having a separable distribution given by the probabilities {q_{ij′}⁰, q_{ij′}¹} for j′≠j. The quantities qᵢⱼ⁰ and qᵢⱼ¹ are variable-to-check messages, while the quantites rᵢⱼ⁰ and rᵢⱼ¹ are check-to-variable messages. It will be appreciated that these four quantities are merely examples of messages and that other messages are also within the scope of the present invention. Moreover, in some algorithms, for example algorithms wherein messages are log of likelihood ratio, only two quantities are calculated/updated in each iteration.

Calculating/updating the values of qᵢⱼ⁰ and qᵢⱼ¹ using the r⁰, r¹ values is termed a ‘vertical pass’, while calculating/updating the values of rᵢⱼ⁰ and rᵢⱼ¹ using the q⁰, q¹ values is termed a ‘horizontal pass’. In more general terms, a ‘vertical pass’ calculates/updates variable-to-check messages based on check-to-variable messages, and a ‘horizontal pass’ calculates/updates check-to-variable messages based on variable-to-check messages.

In the parallel updating method, which is known in the art, each iteration comprises first performing horizontal passes, using for each row the q⁰, q¹ values from the previous iteration, and then performing vertical passes, using for each column the r⁰, r¹ values from the previous iteration. With a single processor, the horizontal passes of an iteration may be performed row by row and the vertical passes of the iteration may be performed column by column. When several processors are used, the horizontal passes of an iteration may be performed substantially simultaneously and the vertical passes of the iteration may be performed substantially simultaneously.

In contrast, the sequential updating method shown in FIG. 4 comprises performing partial horizontal passes for a particular column, then performing a vertical pass for the column and proceeding to the next column. This will now be described in further detail.

Priors Pⱼ⁰ and Pⱼ¹ may represent the statistical information available about the source symbols and the channel noise of the j^{th} symbol of x. Although the present invention is not limited in this respect, for the particular example of evenly distributed source symbols, the priors are Pⱼ⁰=Pⱼ¹=0.5 for the source symbols. Although the present invention is not limited in this respect, for the particular example of a binary symmetric channel (BSC), where each transmitted symbol has a chance f to flip during transmission and a chance 1−f to be transmitted correctly, the priors are Pⱼ⁰=1−f and Pⱼ¹=f for the noise symbols. For other types of channel, the priors may have other values. For example, the channel may be a Gaussian channel. In another example, the source may be biased, having the following priors: Pⱼ⁰=0.7 and Pⱼ¹=0.3.

Initial values may be assigned to qᵢⱼ⁰ and qᵢⱼ⁰ as follows (block 400):

$$\begin{matrix}{q}_{ij}^{1} = {P}_{j}^{1} \\ {q}_{ij}^{0} = {P}_{j}^{0}\end{matrix} ,$$

although other initial stages are also within the scope of the present invention.

The first iteration of the method begins with block 402, at the first column (j=0). For all non-zero elements in column j of matrix H, the values of rᵢⱼ⁰ and rᵢⱼ¹ may be calculated/updated (block 404), as follows:

a) calculating the difference δqᵢⱼ≡qᵢⱼ⁰−qᵢⱼ¹;

b) calculating the difference

$$δ {r}_{i j} ≡ {r}_{i j}^{0} - {r}_{i j}^{1} = {( - 1 )}^{{z}_{i}} {\prod }_{{j}^{′} \neq j} δ {q}_{i {j}^{′}} ;$$

and

c) using the normalization condition rᵢⱼ⁰+rᵢⱼ¹=1 to determine rᵢⱼ⁰ and rᵢⱼ¹ from

$$\begin{matrix}{r}_{ij}^{0} = ( 1 + δ {r}_{ij} ) / 2 \\ {r}_{ij}^{1} = ( 1 - δ {r}_{ij} ) / 2\end{matrix} .$$

For example, referring to FIG. 3, a partial horizontal pass (calculating rᵢⱼ⁰ and rᵢⱼ¹ only for column j) may be performed on column 0 (j=0) as follows:

a) to calculate r_{2,0}⁰ (r_{2,0}¹) using the values of q_{2,4}⁰, q_{2,10}⁰ and q_{2,13}⁰ (q_{2,4}¹, q_{2,10}¹ and q_{2,13}¹);

b) to calculate r_{11,0}⁰ (r_{11,0}¹) using the values of q_{11,6}⁰, q_{11,10}⁰ and q_{11,19}⁰ (q_{11,6}¹, q_{11,10}¹ and q_{11,19}¹); and

c) to calculate r_{14,0}⁰ (r_{14,0}¹) using the values of q_{14,5}⁰, q_{14,8}⁰ and q_{14,17}⁰ (q_{14,5}⁰, q_{14,8}¹ and q_{14,17}¹).

Then a vertical pass for column j may be performed (block 406) using the updated values of rᵢⱼ⁰ and rᵢⱼ¹ calculated in block 404, as follows:

$$\begin{matrix}{q}_{i j}^{0} = {α}_{i j} {P}_{j}^{0} {\prod }_{{i}^{′} \neq i} {r}_{{i}^{′} j}^{0} \\ {q}_{i j}^{1} = {α}_{i j} {P}_{j}^{1} {\prod }_{{i}^{′} \neq i} {r}_{{i}^{′} j}^{1} ,\end{matrix}$$

where αᵢⱼ is a normalization factor chosen to satisfy qᵢⱼ⁰+qᵢⱼ¹=1. The normalization factor may change its value from iteration to iteration.

For example, referring to FIG. 3, a vertical pass (calculating qᵢⱼ¹ and qᵢⱼ⁰ for all values of i) is performed on column 0 (j=0) as follows:

a) to calculate q_{2,0}⁰ (q_{2,0}¹) using the values of r_{11,0}⁰ and r_{14,0}⁰ (r_{11,0}¹ and r_{14,0}¹) calculated/updated in block 404;

b) to calculate q_{11,0}⁰ (q_{11,0}¹) using the values of r_{2,0}⁰ and r_{14,0}⁰ (r_{2,0}¹ and r_{14,0}¹) calculated/updated in block 404; and

c) to calculate q_{14,0}⁰ (q_{14,0}¹) using the values of r_{2,0}⁰ and r_{11,0}⁰ (r_{2,0}¹, and r_{11,0}¹) calculated/updated in block 404.

It is checked whether all of the columns have been updated in the current iteration (block 408). If not, then one advances to the next column (e.g. increments j), and the method continues from block 404.

If all the columns have been updated in the current iteration, then the posterior probability vector Q is calculated for all values of j (block 412), as follows:

$$\begin{matrix}{Q}_{j}^{0} = {α}_{j} {P}_{j}^{0} {\prod }_{i} {r}_{i j}^{0} \\ {Q}_{j}^{1} = {α}_{j} {P}_{j}^{1} {\prod }_{i} {r}_{i j}^{1}\end{matrix} ,$$

where αⱼ is a normalization factor chosen to satisfy Qⱼ⁰+Qⱼ¹=1, and i runs only over non-zero elements. The normalization factor may change its value from iteration to iteration.

Although the present invention is not limited in this respect, the posterior probability vector Q may be clipped to the variable vector x (block 414), as follows:

if Qⱼ¹>0.5 then xⱼ=1; and

if Qⱼ¹<0.5 then xⱼ=0.

A convergence test may then be performed (block 416), for example, testing whether x, given by the symbols xⱼ of block 414, solves H·x=z(mod2). This is substantially equivalent to checking whether the N checks zᵢ are satisfied.

If the iterations have converged to an x that solves H·x=z(mod2), then the method ends. If not, then another iteration begins from block 402, and the calculations of rᵢⱼ⁰ and rᵢⱼ¹ in block 404 are now made using the updated values for qᵢⱼ¹ and qᵢⱼ⁰ from block 406 of the previous iteration.

It should be noted that in the parallel updating method, the calculations/updates performed at each iteration are based solely on the values calculated/updated in the previous iteration. Therefore, there is no intra-iteration information exchange in the parallel updating method. In contrast, the sequential updating method shown in FIG. 4 has the property that when at least one of the quantities corresponding to a matrix element is updated in an iteration, subsequent updates of quantities corresponding to matrix elements in the same row as the matrix element use the updated value of the at least one quantity in the same iteration.

The sequential updating method shown in FIG. 4 may be appropriate for performance by a single processor. However, if more than one processor is available, then the sequential updating method shown in FIG. 4 may be modified in order to perform blocks 404 and 406 for a finite number of columns in parallel. Such a modification may have the effect of reducing the time of a single iteration. For example, if four processors are available, matrix H may be constructed in groups of four consecutive columns such that in each column the non-zero elements are in different rows. With such a construction, the sequential updating method may be applied to a group of four consecutive columns substantially simultaneously and then applied to the subsequent group of four consecutive columns and so on. Although the present invention is not limited in this respect, the number of processors may be 4, 8 or 16 or more.

In the parallel updating method, the values of rᵢⱼ⁰ and rᵢⱼ¹ for all columnsj must be retained for use in the vertical passes. This may lead to high memory consumption. In contrast, with the sequential updating method according to some embodiments of the present invention, the values of rᵢⱼ⁰ and rᵢⱼ¹ for a single column j calculated in block 404 may be stored in memory for use in block 406. It will be appreciated by persons of ordinary skill in the art that if block 404 and block 406 are performed for only one column at a time, then the space in memory for storing the values of rᵢⱼ⁰ and rᵢⱼ¹ may be of a size sufficient for one column only and the space may be overwritten with new values each time one advances to the next column and performs block 404. If block 404 and 406 are performed in parallel for more than one column, then the space will be larger accordingly, but still significantly smaller than the space required in the parallel updating method.

It will be appreciated by persons of ordinary skill in the art that rather than having an iteration comprise a partial horizontal pass followed by a vertical pass for each column in the matrix, the sequential updating method could be modified to have an iteration comprise a partial vertical pass followed by a horizontal pass for each row in the matrix. With such a modification, the sequential updating method has the property that when at least one of the quantities corresponding to a matrix element is updated in an iteration, subsequent updates of quantities corresponding to matrix elements in the same column as the matrix element use the updated value of the at least one quantity in the same iteration. Moreover, if more than one processor is available, then the partial vertical pass followed by a horizontal pass may be performed for a finite number of rows in parallel. Such a modification may have the effect of reducing the time of a single iteration.

SIMULATIONS

Simulations of decoding over a BSC using various rates, block length and flip rates (f) were performed using various constructions for the code and matrices. The distribution of convergence times for the sequential updating method of FIG. 4 and a single-processor parallel updating method were compared by decoding the same codewords (samples) using the two methods.

The comparison of convergence times may be done by monitoring the number of iterations required to reach convergence. A comparison of number of iterations is appropriate because the complexity of a single-processor parallel updating method and the complexity of the single-processor sequential updating method of FIG. 4 are substantially the same.

One of the constructions (the “KS construction”) is described in Ido Kanter, David Saad, “Error-Correcting Codes that Nearly Saturate Shannon's Bound”, Physical Review Letters, vol. 33, number 13, September 1999.

Another of the constructions (the “LMSS construction”) are irregular LDPC codes, following Michael G. Luby, Michael Mitzenmacher, M. Aliin Shokrollahi, and Daniel A. Spielman, “Improved Low-Density Parity-Check Codes Using Irregular Graphs”, IEEE Transactions on Information Theory, 47(2), pp. 585-598, February 2001.

In these constructions, the H matrix was generated at random, distributing the non-zero elements as evenly as possible without violating the constraint of number of elements per row/column. No special attempt was made to select a “good performing” matrix, as no significant difference in the performance (the probability of bit error P_{b}, convergence time) was observed for different matrices.

For the KS construction, the x vector was generated by setting the source symbols to 1 or 0 with probability 0.5. The noise symbols were set to 0 and then exactly a fraction f of the symbols were selected randomly and flipped. The check vector z was computed by z=Hx, and the methods were used to solve Hx′=z. P_{b} was found by comparing x and x′, for the source region only. The source length was selected to be K=10000 and for the rate 1/3 (N=30000) symbols (resulting in x of length 40000 and z of length 30000).

For the LMSS construction, the all-zero codeword was always used as the codeword. The noise vector n was generated as described above for the KS construction. The check vector z was computed, z=Hn, and the methods were used to solve Hn′=z. P_{b} was found by comparing n and n′, since in the LMSS version the “decoding” ends when the noise vector is found and the transmitted vector t is related to the received vector r by t=r+n (mod). A noise vector of length 20000, corresponding to a check vector of size 10000 (rate 1/2).

In both cases, the flip ratefwas selected to be close enough to the critical rate for this block length such that the decoding is characterized by relatively long convergent times. However, the flip ratefwas chosen not too close to the threshold in order to avoid a large fraction of non-converging samples. After the check vector z was constructed, it was decoded both in parallel and sequential schemes, and the number of iterations was monitored.

Three halting criteria were defined for the iterative process:

a) the outcome x′ fully solves Hx′=z;

b) the method reached a stationary state, namely, x′ hasn't changed over the last 10 iterations; and

c) a predefined number of iterations was exceeded (“non-convergence”). This number (500 iterations in the simulations being described) was selected to be by far larger than the average converging time.

### Results

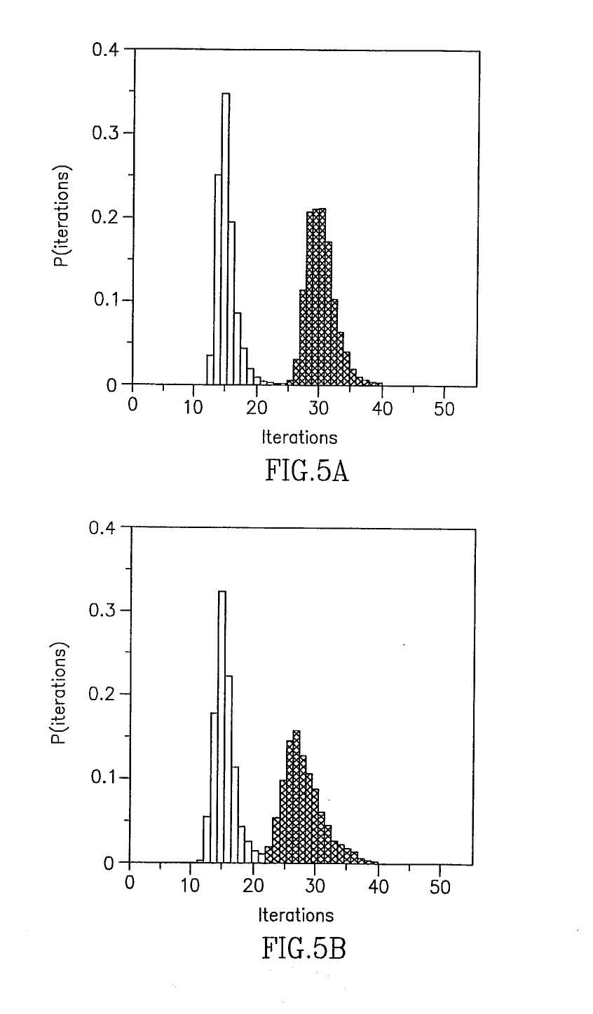

FIGS. 5A and 5B show the distribution of the convergence times (measured in number of iterations) for a single-processor parallel updating method and the sequential updating method of FIG. 4, for KS and LMSS constructions respectively. The code rate is 1/2, channel noise (f) is 0.08 and the block length (N) is 10000. The statistics were collected over 3000 different experiments. The convergence time for the sequential updating method is about one half of the convergence time for the single-processor parallel updating method. The average convergence time for the single-processor parallel updating method is 32.12 iterations for the KS construction, 28.52 iterations for the LMSS construction, while for the sequential updating method of FIG. 4, the average convergence time is 16.7 and 16.32 iterations, respectively. In both constructions the observed bit error rate, P_{b}, after sequential or parallel decoding is the same (P_{b}=O(10⁻⁵)).

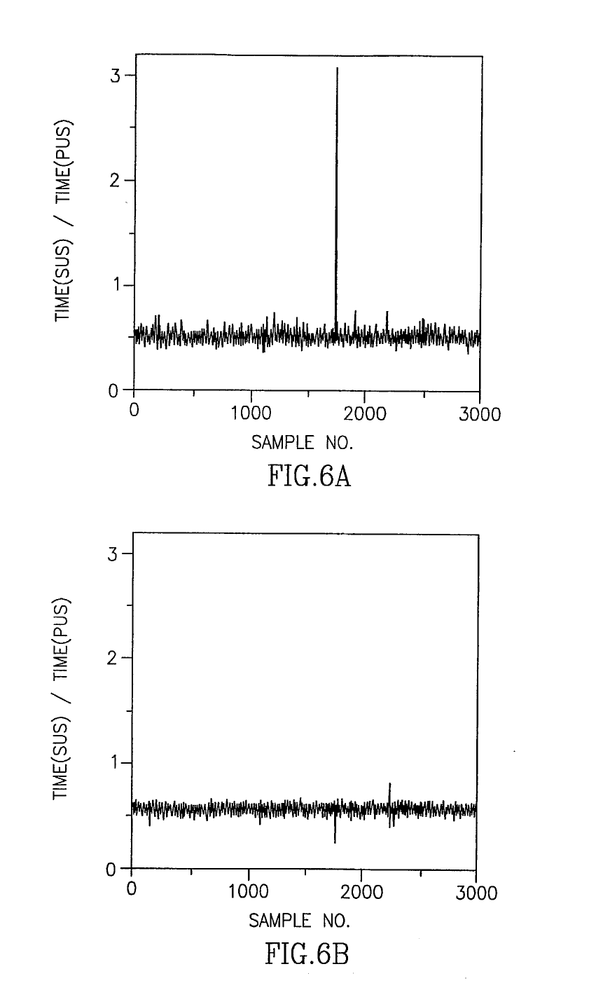

FIGS. 6A and 6B show the ratio between the converging time in sequential/parallel per experiment (sample), for the KS and LMSS constructions respectively. For the vast majority of experiments, this ratio is very close to the average ratio. Therefore, it may be possible to conclude that the double number of iterations for the parallel updating in comparison to the sequential updating is a typical result.

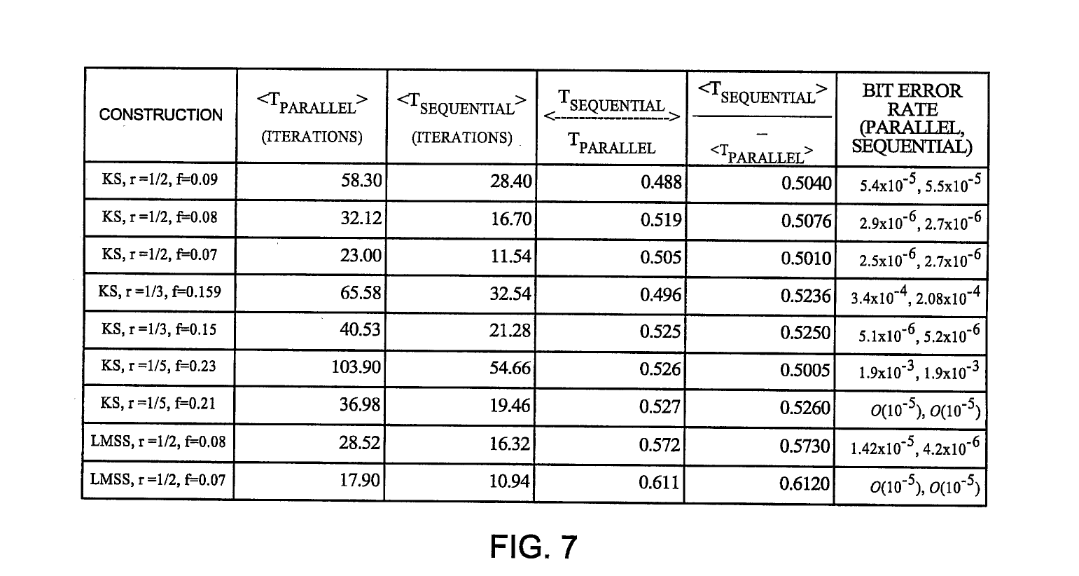

FIG. 7 presents a table of similar measurements for other rates and noise levels. Results indicate that independent of the construction, the noise level and the rate, the convergence time of the parallel updating method may be around double the number of iterations required to achieve convergence in the sequential updating method.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A method comprising:
iteratively decoding a linear block code comprising:
calculating messages corresponding to non-zero elements of a matrix related to said linear block code, said matrix relating variables and checks, such that a checlc-to-variable message calculated during an iteration, whose corresponding matrix element is in a particular row of said matrix, is used in said iteration to calculate other checlc-to-variable messages whose corresponding matrix elements are in said particular row.

2. The method of claim 1, wherein said iteration comprises for each column in said matrix a partial horizontal pass for said column followed by a vertical pass for said column using results of said partial horizontal pass.

3. The method of claim 1, wherein said matrix comprises groups of columns, performing said partial horizontal pass is performed substantially simultaneously for all columns in a group and performing said vertical pass is performed substantially simultaneously for all columns in said group.

4. The method of claim 1, wherein said linear block code is a low-density parity-check code.

5. The method of claim 1, wherein said messages are selected from the group consisting of log-lilcelihood-ratios and probabilities related to said variables and said checks.

6. A method comprising:
iteratively decoding a linear block code comprising:
calculating messages corresponding to non-zero elements of a matrix related to said linear block code, said matrix relating variables and checks, such that a variable-to-check message calculated during an iteration, whose corresponding matrix element is in a particular column of said matrix, is used in said iteration to calculate other variable-to-check messages whose corresponding matrix elements are in said particular column.

7. The method of claim 6, wherein said iteration comprises for each row in said matrix a partial vertical pass for said row followed by a horizontal pass for said row using results of said partial vertical pass.

8. The method of claim 6, wherein said matrix comprises groups of rows, performing said partial vertical pass is performed substantially simultaneously for all rows in a group and performing said horizontal pass is performed substantially simultaneously for all rows in said group.

9. The method of claim 6, wherein said linear block code is a low-density parity-check code.

10. The method of claim 6, wherein said messages are selected from the group consisting of log-likelihood-ratios and probabilities related to said variables and said checks.

11. A method comprising:
for each column in a matrix related to a linear block code, said matrix relating variables and checks:
calculating check-to-variable messages in a partial horizontal pass for said column; and
calculating variable-to-check messages in a vertical pass for said column using results of said partial horizontal pass.

12. The method of claim 11, wherein said partial horizontal pass is performed substantially simultaneously for two or more columns of said matrix, and said vertical pass is performed substantially simultaneously for said two or more columns.

13. A method comprising:
for each row in a matrix related to a linear block code, said matrix relating variables and checks:
calculating variable-to-check messages in a partial vertical pass for said row; and
calculating check-to-variable messages in a horizontal pass for said row using results of said partial vertical pass.

14. The method of claim 13, wherein said partial vertical pass is performed substantially simultaneously for two or more rows of said matrix, and said horizontal pass is performed substantially simultaneously for said two or more rows.

15. An article comprising a storage medium having stored thereon instructions that, when executed by a computing platform, result in:
iteratively decoding a linear block code comprising:
calculating messages corresponding to non-zero elements of a matrix related to said linear block code, said matrix relating variables and checks, such that a check-to-variable message calculated during an iteration, whose corresponding matrix element is in a particular row of said matrix, is used in said iteration to calculate other check-to-variable messages whose corresponding matrix elements are in said particular row.

16. The article of claim 15, wherein said iteration comprises for each column in said matrix a partial horizontal pass for said column followed by a vertical pass for said column using results of said partial horizontal pass.

17. An article comprising a storage medium having stored thereon instructions that, when executed by a computing platform, result in:
iteratively decoding a linear block code comprising:
calculating messages corresponding to non-zero elements of a matrix related to said linear block code, said matrix relating variables and checks, such that a variable-to-check message calculated during an iteration, whose corresponding matrix element is in a particular column of said matrix, is used in said iteration to calculate other variable-to-check messages whose corresponding matrix elements are in said particular column.

18. The article of claim 17, wherein said iteration comprises for each row in said matrix a partial vertical pass for said row followed by a horizontal pass for said row using results of said partial vertical pass.

19. An apparatus comprising:
a decoder to decode a signal encoded by a linear block code by calculating messages corresponding to non-zero elements of a matrix related to said linear block code, said matrix relating variables and checks, such that a check-to-variable message calculated during an iteration, whose corresponding matrix element is in a particular row of said matrix, is used in said iteration to calculate other check-to-variable messages whose corresponding matrix elements are in said particular row.

20. The apparatus of claim 19, wherein said linear block code is a low-density pality-check code.

21. The apparatus of claim 19, wherein said messages are probabilities related to said variables and said checks.

22. A communication device comprising:
a radio frequency antenna to receive a signal encoded by a linear block code; and
a decoder to decode a demodulated version of said signal, said decoder comprising:
a computing unit to calculate messages corresponding to non-zero elements of a matrix related to said linear block code, said matrix relating variables and checks, such that a check-to-variable message calculated during an iteration, whose corresponding matrix element is in a particular row of said matrix, is used in said iteration to calculate other check-to-variable messages whose corresponding matrix elements are in said particular row.

23. The communication device of claim 22, further comprising:
a memory coupled to said computing unit, said memory comprising storage space, and wherein said computing unit is able to store in said storage space check-to-variable messages corresponding to a column of said matrix and calculated during said iteration such that check-to-variable messages corresponding to another column of said matrix and calculated earlier during said iteration are overwritten.

24. The communication device of claim 22, wherein said computing unit is a digital signal processor.

25. A communication system comprising:
a first communication device to transmit a signal encoded with a linear block code through a communication channel; and
a second communication device to receive said signal and to calculate messages corresponding to non-zero elements of a matrix related to said linear block code, said matrix relating variables and checks, such that a check-to-variable message calculated during an iteration, whose corresponding matrix element is in a particular row of said matrix, is used in said iteration to calculate other checlc-to-variable messages whose corresponding matrix elements are in said particular row.

26. The communication system of claim 25, wherein said communication channel is a wide-area-network and said second communication device comprises a modem.

27. The communication system of claim 25, wherein said communication channel is a local-area-network and said second communication device comprises a modem.

28. The communication system of claim 25, wherein said signal is a radio frequency signal.

29. The communication system of claim 25, wherein said communication system comprises a Wideband Code Division Multiple Access communication system.
